(19) United States
(12) Patent Application Publication
(10) Pub. No.: US 2024/0128098 A1
(43) Pub. Date: Apr. 18, 2024

(54) EXPANDER AND SEMICONDUCTOR MANUFACTURING EQUIPMENT INCLUDING THE SAME

(71) Applicant: SAMSUNG ELECTRONICS CO., LTD., SUWON-SI (KR)

(72) Inventor: Young Hun KIM, Suwon-si (KR)

(21) Appl. No.: 18/216,675

(22) Filed: Jun. 30, 2023

(30) Foreign Application Priority Data
Oct. 12, 2022 (KR) 10-2022-0130585
Dec. 9, 2022 (KR) 10-2022-0171263

(51) Int. Cl. H01L 21/67; B65G 47/90; H01L 21/683

(52) U.S. Cl. CPC H01L 21/67132; B65G 47/90; H01L 21/6836

(57) ABSTRACT

A semiconductor manufacturing equipment includes: a first clamp fixing a dicing tape, on which a plurality of divided dies are disposed, and configured to ascend and descend; and a first expander adjacent to the first clamp and including a body, a first protrusion connected to the body, and a second protrusion connected to the body and spaced apart from the first protrusion, wherein, when no pressure is exerted on the first protrusion and the second protrusion, the first protrusion and the second protrusion protrude from the body, and wherein, when a pressure is exerted on the first protrusion and the second protrusion, the first protrusion and the second protrusion descend into the body depending on a magnitude of the pressure exerted on the first protrusion and the second protrusion.

### CROSS-REFERENCE TO RELATED APPLICATION

This application claims priority under 35 USC § 119 to Korean Patent Applications No. 10-2022-0130585 filed on Oct. 12, 2022 and No. 10-2022-0171263 filed on Dec. 9, 2022 in the Korean Intellectual Property Office, the disclosures of which are incorporated by reference herein in their entireties.

### TECHNICAL FIELD

The present inventive concept relates to an expander and a semiconductor manufacturing equipment including the same.

### DISCUSSION OF THE RELATED ART

Generally, a semiconductor package process includes a sawing process of cutting a wafer and dividing it into dies which are semiconductor chips. The process may further include a die attach process of attaching the divided dies to a substrate. The process may additionally include a process of electrically connecting connection pads of the die and the substrate to each other. The process may also include a molding process of molding peripheries of the dies, and a process of forming external connection terminals on the ball pads of the substrate.

A dicing tape may be attached to a back side of the wafer to prevent the dies from falling off during the sawing process. In the die attach process, the dicing tape is extended to increase an interval (or a cuff width) between the dies located on the dicing tape. After that, a die selected from the dies is picked up. If the cuff width is not sufficient, a risk of die breakage may occur during the pick-up process of the selected die.

### SUMMARY

According to an exemplary embodiment of the present inventive concept, a semiconductor manufacturing equipment includes: a first clamp fixing a dicing tape, on which a plurality of divided dies are disposed, and configured to ascend and descend; and a first expander adjacent to the first clamp and including a body, a first protrusion connected to the body, and a second protrusion connected to the body and spaced apart from the first protrusion, wherein, when no pressure is exerted on the first protrusion and the second protrusion, the first protrusion and the second protrusion protrude from the body, and wherein, when a pressure is exerted on the first protrusion and the second protrusion, the first protrusion and the second protrusion descend into the body depending on a magnitude of the pressure exerted on the first protrusion and the second protrusion.

According to an exemplary embodiment of the present inventive concept, an expander includes: an annular-shaped body; a first groove and a second groove spaced apart from each other inside the annular-shaped body; a first elastic body disposed inside the first groove; a second elastic body disposed inside the second groove; a first protrusion, which is connected to the first elastic body, standing by at a first position that is protruding from the annular-shaped body, wherein the first protrusion is configured to enter the first groove when a force is applied to the first protrusion by a dicing tape, and is configured to move to a second position; and a second protrusion, which is connected to the second elastic body, standing by at a third position that is protruding from the annular-shaped body, wherein the second protrusion is configured to enter the second groove when a force is applied to the second protrusion by the dicing tape, and is configured to move to a fourth position.

According to an exemplary embodiment of the present inventive concept, a semiconductor manufacturing equipment includes: a first clamp fixing a dicing tape, on which a plurality of divided dies are disposed, and is configured to ascend and descend; a die ejector disposed below the dicing tape, and configured to select a die that is to be picked up, among the plurality of divided dies; and a first expander disposed between the first clamp and the die ejector and configured to expand the dicing tape as the first clamp descends, wherein the first expander includes: an annular-shaped body; a first groove and a second groove which are disposed inside the annular-shaped body and disposed symmetrically with each other on a basis of a center of the annular-shaped body; a first elastic body disposed inside the first groove; a second elastic body disposed inside the second groove; a first protrusion, which is connected to the first elastic body, standing by at a first position that is protruding from the annular-shaped body, wherein the first protrusion is configured to move to a second position along the first groove when a force is applied to the first protrusion by the dicing tape; and a second protrusion, which is connected to the second elastic body, standing by at a third position that is protruding from the annular-shaped body, wherein the second protrusion is configured to move to a fourth position along the second groove when a force is applied to the second protrusion by the dicing tape.

### BRIEF DESCRIPTION OF THE DRAWINGS

The above and features of the present inventive concept will become more apparent by describing in detail exemplary embodiments thereof with reference to the attached drawings, in which:

FIG. 1 is a schematic plan view illustrating semiconductor manufacturing equipment according to an exemplary embodiment of the present inventive concept;

FIG. 2 is a schematic side view illustrating a die transport module shown in FIG. 1;

FIG. 3 is a schematic side view illustrating a die attach module shown in FIG. 1:

FIG. 4 is a perspective view of an expander shown in FIG. 2;

FIG. 5 is a cross-sectional view taken along V-V of FIG. 4;

FIG. 6 is a plan view of the expander shown in FIG. 2;

FIG. 7 is a side view illustrating the shape of the expander when a clamp is positioned at a first height;

FIG. 8 is a plan view illustrating the placement of dies positioned on the dicing tape when the clamp is positioned at the first height;

FIG. 9 is a side view illustrating the shape of the expander when the clamp descends below the first height;

FIG. 10 is a plan view illustrating the placement of the dies positioned on the dicing tape when the clamp descends below the first height;

FIG. 11 is a side view illustrating the shape of the expander when the clamp descends to a second height;

FIG. 12 is a plan view illustrating the placement of dies positioned on the dicing tape when the clamp descends to the second height;

FIGS. 13 and 14 are diagrams illustrating placement examples of the extender used in the semiconductor manufacturing equipment according to an exemplary embodiment of the present inventive concept; and

FIGS. 15 and 16 are diagrams illustrating other examples of the extender used in the semiconductor manufacturing equipment according to some exemplary embodiments of the present inventive concept.

### DETAILED DESCRIPTION OF THE EMBODIMENTS

Exemplary embodiments of the present inventive concept will be described in detail below with reference to the accompanying drawings. The same reference numerals may be used for the same components throughout the specification and the drawings, and repeated descriptions thereof might not be provided or may be briefly discussed.

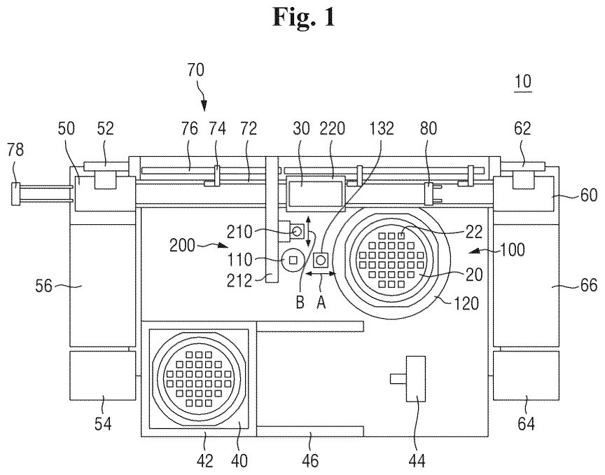

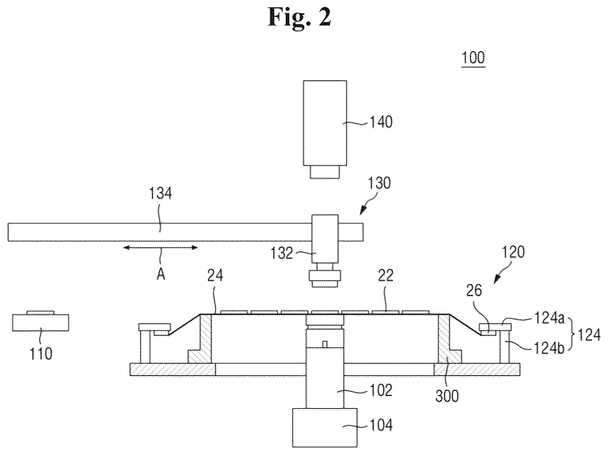

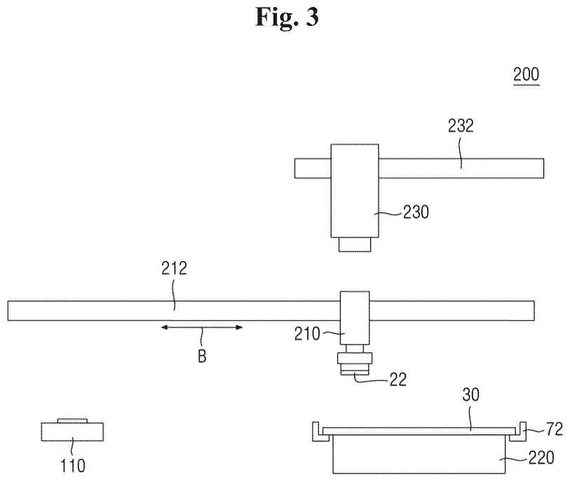

FIG. 1 is a schematic plan view illustrating semiconductor manufacturing equipment according to an exemplary embodiment of the present inventive concept. FIG. 2 is a schematic side view illustrating a die transport module shown in FIG. 1, and FIG. 3 is a schematic side view illustrating a die attach module shown in FIG. 1. Although FIG. 1 shows a die attach equipment for attaching a die divided by a sawing process onto a substrate such as a printed circuit board or a lead frame as an example of a semiconductor manufacturing equipment, the present inventive concept is not limited thereto.

Referring to FIGS. 1 to 3, a semiconductor manufacturing equipment 10 according to an exemplary embodiment of the present inventive concept includes a die transport module 100 and a die attach module 200. The die transport module 100 picks up a die 22 from a wafer 20 and transports it to an intermediate position (e.g., a die stage 110). The die attach module 200 picks up the die 22 at the intermediate position, and attaches it onto the substrate 30.

The wafer 20 includes a plurality of dies 22 attached onto a dicing tape 24, and the plurality of dies 22 are divided. The dicing tape 24 may be fixed by a mount frame 26. As shown, the mount frame 26 may have the form of a circular ring or an annular shape. For example, the dicing tape 24 may be attached onto a lower surface of the mount frame 26, and the plurality of dies 22 may be attached onto an upper surface of the dicing tape 24.

The die transport module 100 includes a wafer stage 120, a die transport unit 130, a camera unit 140, and the like.

The wafer stage 120 is for supporting the wafer 20. The wafer stage 120 has an expander 300 and a clamp unit 124. The expander 300 is for supporting the dicing tape 24 in the process of expanding the dicing tape 24, and the clamp unit 124 is for lowering the dicing tape 24 (i.e., the mount frame 26) to expand the dicing tape 24.

The expander 300 is placed inside the clamp unit 124. The expander 300 is located between a die ejector 102 and the clamp unit 124.

The clamp unit 124 includes a clamp 124a and a clamp driver 124b. The clamp 124a is for fixing the dicing tape (that is, the mount frame 26), and the clamp driver 124b is for raising and lowering the clamp 124a. For example, the clamp driver 124b may include an actuator and/or a motor (e.g., a micro motor).

Although it will be described in detail below, a process of expanding the dicing tape 24 on the wafer stage 120 will be briefly described. The expander 300 supports the dicing tape 24 between the plurality of dies 22 and the mount frame 26. In a state in which the expander 300 supports the dicing tape 24, the clamp unit 124 may expand the dicing tape 24 by further lowering the mount frame 26 on which the dicing tape 24 is mounted. Further, an interval (or a cuff width) between the plurality of dies 22 may be expanded, by expansion of the dicing tape 24.

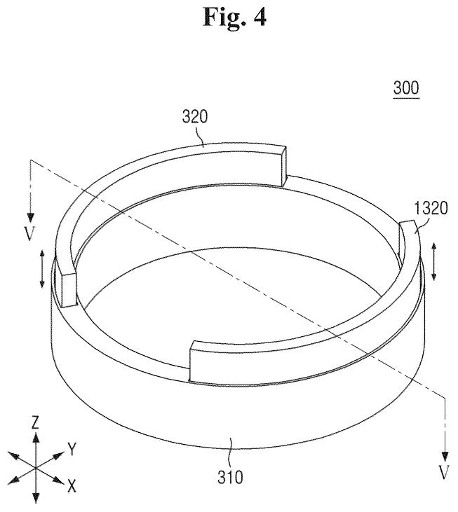

In an exemplary embodiment of the present inventive concept, the expander 300 includes a plurality of protrusions (see 320 and 1320 of FIG. 4) installed to be spaced apart and movable in a vertical direction. A larger force is exerted in a preset direction when the dicing tape 24 is expanded, by using the plurality of protrusions 320 and 1320. This allows the interval between the plurality of dies 22 to be adjusted differently depending on the direction. This will be described below using FIGS. 4 to 11.

In addition, a die ejector 102 is placed under the dicing tape 24 that is supported by the expander 300. The die ejector 102 may selectively separate the die 22, among the plurality of dies 22, that are to be picked up from the dicing tape 24. For example, the die ejector 102 separates the die 22 that are to be picked up from the dicing tape 24, by lifting (that is, pushing up) the die 22 that are to be picked up, among the plurality of dies 22. The die ejector 102 may include vacuum holes for vacuum-sucking the lower surface of the dicing tape 24. For example, a vacuum 104 may be connected to the die ejector 102 so that the die ejector 102 may apply a vacuum suction force.

The die transport unit 130 picks up the plurality of dies 22 positioned on the wafer stage 120 one by one and transports them onto the die stage 110. Such a die transport unit 130 includes a picker 132 and a picker driver 134.

The picker 132 is placed above the wafer stage 120, and picks up the die 22 that is separated from the dicing tape 24 by the die ejector 102. The picker 132 may pick up die 22, for example, in a vacuum manner. The picker 132 may include a collet formed with a vacuum hole for vacuum-sucking the die 22.

In addition, the picker driver 134 moves the picker 132 in the vertical and horizontal directions (see reference numeral A). For example, the picker driver 134 may include an actuator and/or a motor. The die stage 110 may be placed to be spaced apart from the wafer stage 120 in the horizontal direction, and the die 22 picked up by the picker 132 may be transported onto the die stage 110 by the picker driver 134.

The camera unit 140 is positioned above the wafer stage 120 to detect the die 22 that are to be picked up among the plurality of dies 22. For example, the camera unit 140 includes a camera.

In addition, the wafer stage 120 may be moved in the horizontal direction. For this purpose, a stage driver for moving the wafer stage 120 may be provided. The stage driver may adjust the position of the wafer stage 120 so that the die 22 to be picked up, among the plurality of dies 22, is positioned above the die ejector 102. For example, the stage driver may include an actuator and/or a motor.

In addition, as shown in FIG. 1, the semiconductor manufacturing equipment 10 may further include a cassette load port 42 in which a cassette 40 for accommodating the wafers 20 is placed. The semiconductor manufacturing equipment 10 may further include a wafer transport unit 44 for transporting the wafer 20 from the cassette 4 onto the wafer stage 120, and a wafer guide rail 46 for guiding the transport of the wafer 20. For example, the stage driver may move the wafer stage 120 to be adjacent to the end of the wafer guide rail 46, and then, the wafer transport unit 44 may move the wafer 20 from the cassette 40 onto the wafer stage 120. The wafer transport unit 44 may include a gripper for gripping the mount frame 26, and a gripper driver for moving the gripper in the horizontal direction. For example, the gripper driver may include an actuator and/or a motor.

The die attach module 200 may pick up the die 22 that is transported onto the die stage 110, and may attach it onto the substrate 30.

The die attach module 200 may include a head 210 for picking up the die 22, a head driver 212 for moving the head 210 (see reference numeral B) in the vertical and horizontal directions, and a substrate stage 220 for supporting the substrate 30.

For example, the head driver 212 may include an actuator and/or a motor.

The head 210 has vacuum holes for vacuum-sucking the die 22, and may include a bonding tool for pressing the die 22 onto the substrate 30. The substrate stage 220 may also include a heater for heating the substrate 30 to a preset temperature for attachment of the die 22 to the substrate 30.

In addition, the die attach module 200 may further include a camera unit 230, which is placed above the substrate stage 220 to detect a region of the die 22 that is to be bonded on the substrate 30, and a camera driver 232 for adjusting the positions of the camera unit 140. For example, the camera driver 232 may include an actuator and/or a motor.

The substrate 30 may be supplied from a first magazine 50, and accommodated in a second magazine 60 after the die bonding process is completed. For example, the semiconductor manufacturing equipment 10 has a first magazine handling unit 52 for handling the first magazine 50, and a second magazine handling unit 62 for handling the second magazine 60. Further, the semiconductor manufacturing equipment 10 may further include a first magazine load port 54 in which the first magazine 50 is placed, and a second magazine load port 64 in which the second magazine 60 is placed. The semiconductor manufacturing equipment 10 may further include a first magazine transport unit 56 that transports the first magazine 50 between the first magazine load port 54 and the first magazine handling unit 52, and a second magazine transport unit 66 that transports the second magazine 60 between the second magazine load port 64 and the second magazine handling unit 62.

The semiconductor manufacturing equipment 10 may further include a substrate transport unit 70 which transports the substrate 30 from the first magazine 50 onto the substrate stage 220, adjusts the position of the substrate 30 on the substrate stage 220, and transports the substrate 30 to the second magazine 60 after completing the die bonding process.

The substrate transport unit 70 includes a substrate guide rail 72, a gripper 74, a gripper driver 76, a first pusher 78, and a second pusher 80. The substrate guide rail 72 is for guiding the transport of the substrate 30, and the gripper 74 is for gripping the substrate 30. The gripper driver 76 is for moving the gripper 74, and the first pusher 78 is for moving the substrate 30 onto the substrate guide rail 72. The second pusher 80 is for moving the substrate 30 on the substrate guide rails 72 into the second magazine 60.

A structure of the expander will be specifically described below with reference to FIGS. 4 to 6.

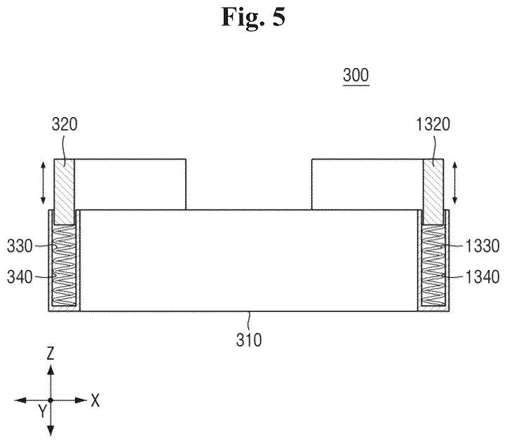

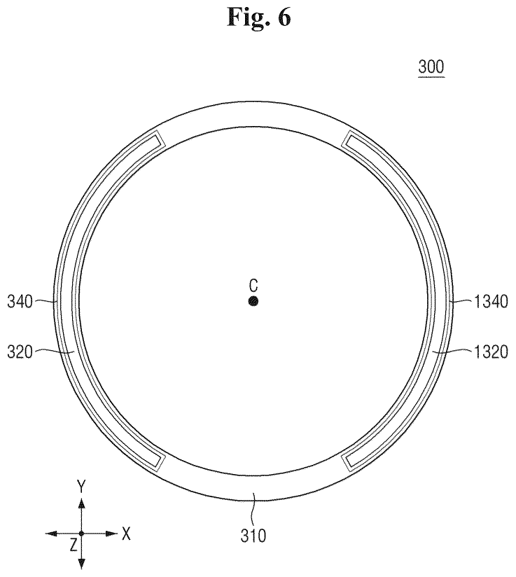

FIG. 4 is a perspective view of the expander shown in FIG. 2. FIG. 5 is a cross-sectional view taken along V-V of FIG. 4. FIG. 6 is a plan view of the expander shown in FIG. 2.

Referring to FIGS. 4 to 6, the expander 300 includes a body 310, a first protrusion 320, a second protrusion 1320, a first elastic body 330, a second elastic body 1330, a first groove 340, and a second groove 1340.

The body 310 may have, but is not limited to, an annular shape.

The first groove 340 and the second groove 1340 are spaced apart from each other inside the body 310. As shown, the first groove 340 and the second groove 1340 are spaced apart from each other in a first direction X.

When the body 310 has an annular shape, the first groove 340 and the second groove 1340 may be placed at symmetrical positions in the first direction X on the basis of the center C of the annular shape. In addition, when the body 310 has an annular shape, the first groove 340 and the second groove 1340 may have an arc shape.

The first elastic body 330 is placed inside the first groove 340, and the second elastic body 1330 is placed inside the second groove 1340.

The first elastic body 330 and the second elastic body 1330 may be any material as long as it achieves elasticity in mechanical, electrical or chemical manner. Although springs are shown as an example of the first elastic body 330 and the second elastic body 1330 in the drawing, the present inventive concept is not limited thereto. For example, the first elastic body 330 and the second elastic body 1330 may be implemented in various ways such as a sponge, a solenoid, an elastomer, a magnet, and the like.

The first protrusion 320 is connected to the first elastic body 330 and may move along the first groove 340 (that is, along the inner walls of the first groove 340). For example, the first protrusion 320 may stand by at a first position protruding from the body 310, may enter the first groove 340 by the exerted pressure, and may move to a second position. For example, if the pressure is not exerted on the first protrusion 320, the first protrusion 320 remains protruding from the body 310, and if the pressure is exerted on the first protrusion 320, it may descend into the first groove 340 depending on the magnitude of the pressure. In an exemplary embodiment of the present inventive concept, as the clamp (124a of FIG. 2) descends, the dicing tape 24 exerts a force on the first protrusion 320, and the first protrusion 320 descends along the first groove 340 by the force pressed by the dicing tape 24.

Similarly, the second protrusion 1320 is connected to the second elastic body 1330 and may move along the second groove 1340 (that is, along the inner walls of the second groove 1340). For example, the second protrusion 1320 may stand by at a third position protruding from the body 310, may enter the second groove 1340 by the exerted pressure, and may move to a fourth position. For example, if the pressure is not exerted on the second protrusion 1320, it may remain protruding from the body 310, and if the pressure is exerted on the second protrusion 1320, it may descend into the second groove 1340 depending on the magnitude of the pressure. In an exemplary embodiment of the present inventive concept, as the clamp (124a of FIG. 2) descends, the dicing tape 24 exerts a force on the second protrusion 1320, and the second protrusion 1320 descends along the second groove 1340 by the force pressed by the dicing tape 24.

The first protrusion 320 may have, but is not limited to, an arc shape corresponding to the shape of the body 310 and the first groove 340. The second protrusion 1320 may have, but is not limited to, an arc shape corresponding to the shapes of the body 310 and the second groove 1340.

In the expander 300, the first protrusion 320 and the second protrusion 1320 are positioned in the first direction X, and such protrusions are not positioned in the second direction Y.

Since the expander 300 has such a shape, the dicing tape 24 may be relatively more stretched in the first direction X, and the dicing tape 24 may be relatively less stretched in the second direction Y. By doing so, it is possible to sufficiently increase the interval between the plurality of dies 22 in the first direction X (that is, the cuff width).

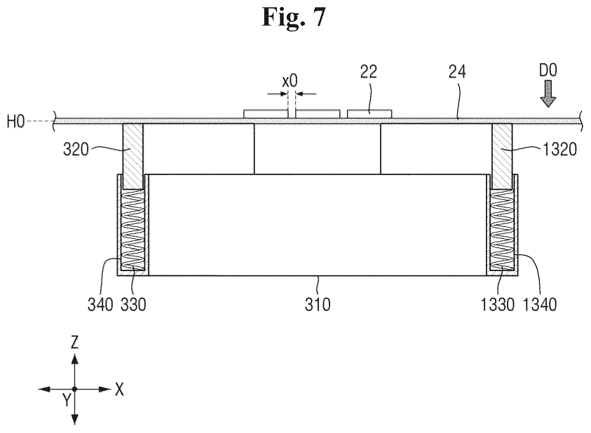

The operation of such an expander will be specifically described below with reference to FIGS. 7 to 12.

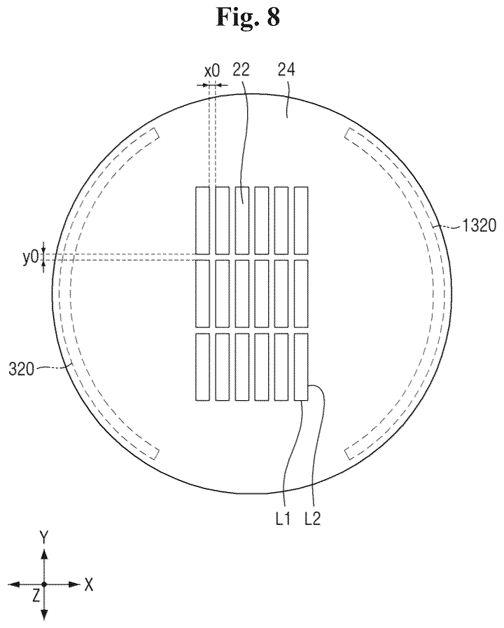

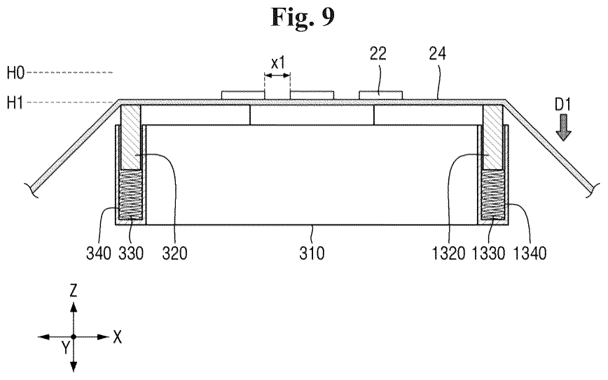

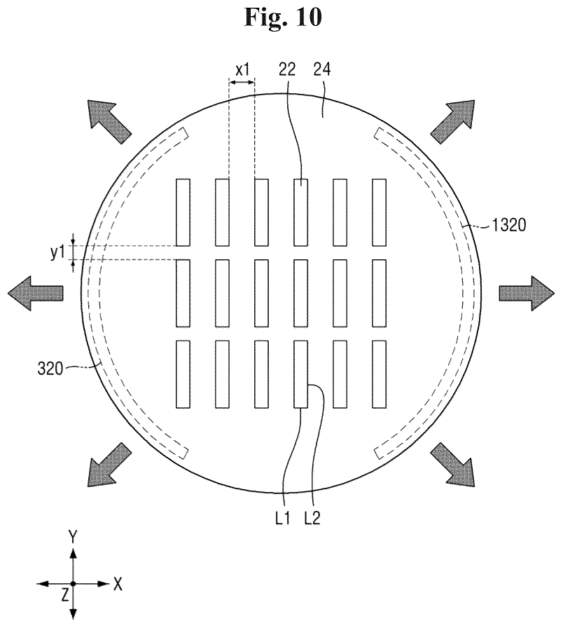

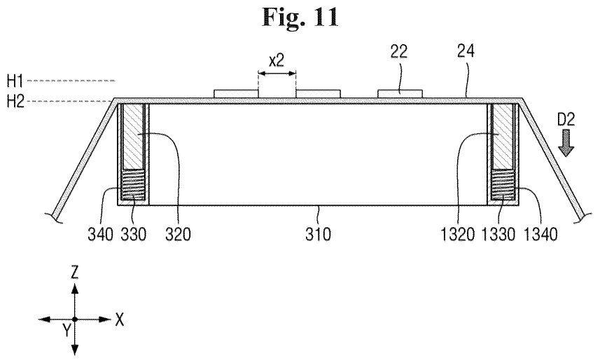

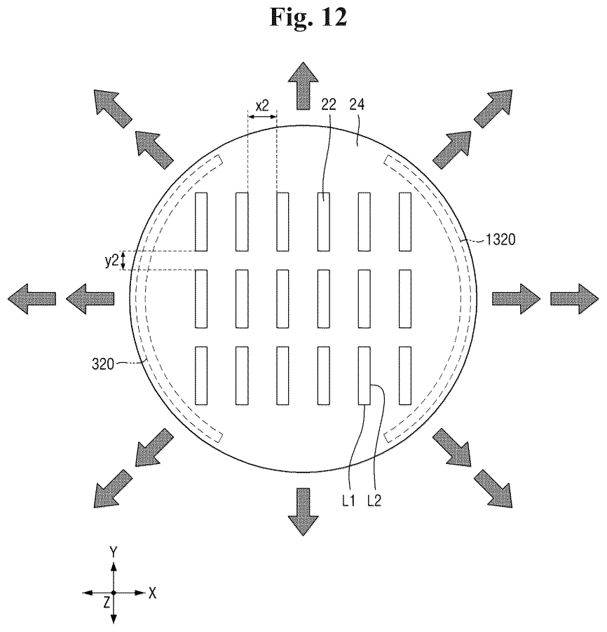

FIG. 7 is a side view illustrating the shape of the expander when the clamp is positioned at the first height. FIG. 8 is a plan view illustrating the placement of dies positioned on the dicing tape when the clamp is positioned at the first height. FIG. 9 is a side view illustrating the shape of the expander when the clamp descends below the first height. FIG. 10 is a plan view illustrating the placement of the dies positioned on the dicing tape when the clamp descends below the first height. FIG. 11 is a side view illustrating the shape of the expander when the clamp descends to the second height. FIG. 12 is a plan view illustrating the placement of dies positioned on the dicing tape when the clamp descends to the second height.

First, referring to FIGS. 7 and 8, the dicing tape 24 (that is, the mount frame 26) is fixed to the clamp 124a.

A plurality of dies 22 may be placed on the dicing tape 24. As shown, although the plurality of dies 22 may be arranged in the form of a matrix in the first direction X and the second direction Y, the present inventive concept is not limited thereto.

For example, the die 22 may have a substantially rectangular shape. For example, the die 22 has a first length L1 in the first direction X and a second length L2 in the second direction Y, and the first length L1 is shorter than the second length L2.

The interval between adjacent dies 22 in the first direction X (i.e., the cuff width in the first direction X) is x0. The interval between adjacent dies 22 in the second direction Y (i.e., the cuff width in the second direction Y) is y0.

The dicing tape 24 may be brought into contact with the upper surface of the first protrusion 320 and the upper surface of the second protrusion 1320 when the clamp (124a of FIG. 2) is positioned at a first height H0. Almost no pressure D0 is exerted on the dicing tape 24 when the clamp (124a of FIG. 2) is positioned at the first height H0.

Referring to FIGS. 9 and 10, as the clamp (124a of FIG. 2) descends below the first height H0 (see reference numeral H1), the dicing tape 24 presses the first protrusion 320 and the second protrusion 1320 to descend. A pressure D1 with which the dicing tape 24 presses the first protrusions 320 and the second protrusions 1320 is greater than a pressure D0 shown in FIG. 7.

In addition, as the clamp 124a descends, the dicing tape 24 is relatively more stretched in the first direction X, by the first protrusion 320 and the second protrusion 1320 spaced apart from each other in the first direction X in the expander 300.

In addition, since the expander 300 does not have protrusions that are arranged in the second direction Y, the dicing tape 24 is relatively less stretched in the second direction Y.

Therefore, as the clamp 124a descends, the interval between the adjacent dies 22 in the first direction X (i.e., the cuff width in the first direction X) becomes x1 which is greater than x0. The interval between the adjacent dies 22 in the second direction Y (that is, the cuff width in the second direction Y) is y1 which is greater than y0.

For example, since the dicing tape 24 is considerably stretched in the first direction X, an amount of increase (i.e., x1/x0) in cuff width in the first direction X may be greater than an amount of increase (i.e., y1/y0) in cuff width in the second direction Y.

Referring to FIGS. 11 and 12, as the clamp (124a of FIG. 2) continues to descend to the second height H2, the dicing tape 24 is brought into contact with the first protrusion 320, the second protrusion 1320, and the body 310. The pressure D2 with which the dicing tape 24 presses the first protrusion 320 and the second protrusion 1320 is greater than the pressure D1 shown in FIG. 9.

Since the dicing tape 24 is brought into contact with the upper surfaces of the first protrusion 320, the second protrusion 1320 and the body 310, the dicing tape 24 is stretched in all directions including the first direction X and the second direction Y.

When the clamp 124a descends to the second height H2, the interval between the adjacent dies 22 in first direction X (i.e., cuff width in first direction X) becomes x2 greater than x1. The interval between the adjacent dies 22 in the second direction Y (that is, the cuff width in the second direction Y) becomes y2 which is greater than y1.

In summary, when the die 22 has a substantially rectangular shape, and the upper surface of the expander 300 is flat with no steps, even if the clamp 124a descends to expand the dicing tape 24, the cuff width might not be sufficiently ensured in a particular direction (e.g., the first direction X). In this case, a risk such as die breakage may occur in the die pickup process.

In addition, according to the semiconductor manufacturing equipment 10 according to an exemplary embodiment of the present inventive concept, a sufficient cuff width in a specific direction (e.g., the first direction X) can be ensured, using the protrusions 320 and 1320 which are spaced apart in a first specific direction (e.g., the first direction X) and may descend by the pressed force. Therefore, it is possible to reduce a risk such as die breakage in the die pick-up process.

In addition, when there is a structure, in which the protrusions spaced apart in the first direction X are fixed without descending, even if the clamp 124a descends to expand the dicing tape 24, since a sufficient force of pulling the dicing tape 24 in the second direction Y might not be provided, a sufficient cuff width in the second direction Y might not be ensured.

In addition, according to an exemplary embodiment of the present inventive concept, the semiconductor manufacturing equipment 10 may include both a first wafer stage (see 120 of FIG. 2) including an extender provided with the protrusions 320 and 1320, and a second wafer stage provided with no protrusion and including an expander having a flat upper. For example, the second wafer stage is provided with a clamp that is able to ascend and descend, and an extender that has a flat upper surface inside the clamp. Depending on the shape of the die 22, the first wafer stage may be used or the second wafer stage may be selectively used. For example, the first wafer stage may be used if the die has a substantially rectangular shape, and the second wafer stage may be used if the die has a substantially square shape.

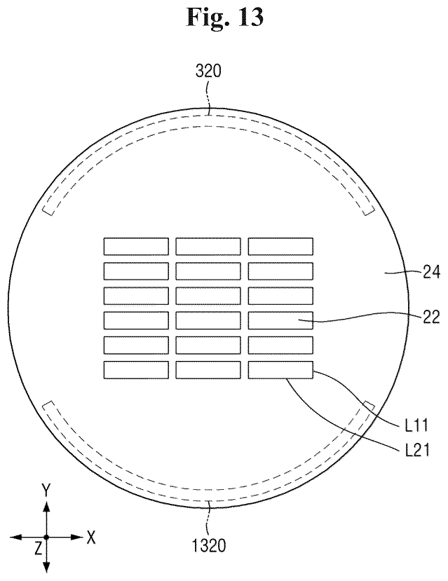

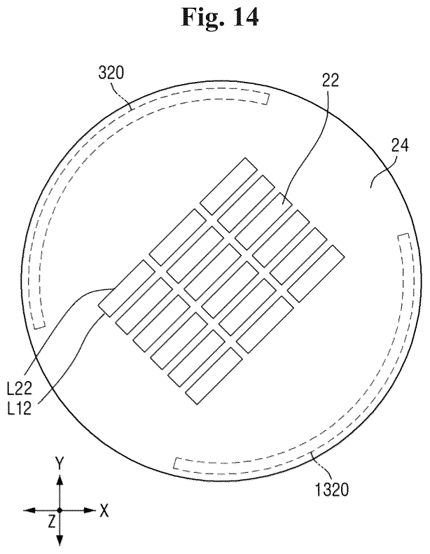

FIGS. 13 and 14 are diagrams illustrating placement examples of an extender used in the semiconductor manufacturing equipment according to an exemplary embodiment of the present inventive concept. For convenience of explanation, points and/or descriptions that are different from FIG. 8 will be mainly described, and redundant or repetitive descriptions will be omitted or briefly discussed.

Installation directions of the first protrusion 320 and the second protrusion 1320 may be made different in consideration of a placement direction of the die 22.

Specifically, in FIG. 8, the die 22 has a first length L1 in the first direction X and a second length L2 in the second direction Y, and the first length L1 is shorter than the second length L2. Therefore, to ensure a sufficient cuff width in the first direction X, the first protrusion 320 and the second protrusion 1320 are spaced apart from each other in the first direction X.

In addition, in FIG. 13, the die 22 includes a relatively short first length L11 and a relatively long second length L21. The first length L11 extends in the second direction Y, and the second length L21 extends in the first direction X. Therefore, to ensure a sufficient cuff width in the second direction Y, the first protrusion 320 and the second protrusion 1320 are spaced apart from each other in the second direction Y.

In FIG. 14, the die 22 includes a relatively short first length L12 and a relatively long second length L22. The first length L12 extends in a first diagonal direction (e.g., a 4 o'clock direction) between the first direction X and the second direction Y, and the second length L22 extends in a second diagonal direction (e.g., a 1 o'clock direction) crossing the first diagonal direction. Therefore, to ensure a sufficient cuff width in the first diagonal direction, the first protrusion 320 and the second protrusion 1320 are placed apart from each other in the first diagonal direction.

As another example, the placement direction of the die 22 is grasped by using a camera unit (e.g., see 140 of FIG. 2), and a rotary driver may rotate the expander 300 depending on the placement direction of the die 22. For example, if a relatively short first length of the die 22 extends in the second direction Y, the expander 300 may be rotated such that the first protrusion 320 and the second protrusion 1320 are spaced apart from each other in the second direction Y before expanding the dicing tape.

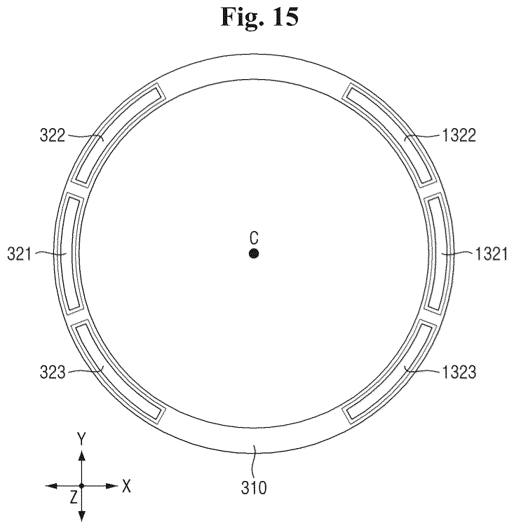

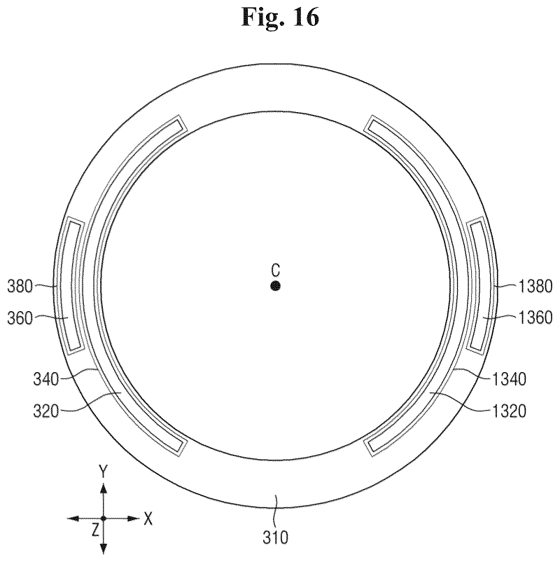

FIGS. 15 and 16 are diagrams illustrating other examples of an extender used in a semiconductor manufacturing facility according to some exemplary embodiments of the present inventive concept. For convenience of explanation, points and/or descriptions that are different from FIG. 8 will be mainly described, and redundant or repetitive descriptions will be omitted or briefly discussed.

Referring to FIG. 15, the first protrusion is divided into a plurality of portions 321, 322, and 323. For example, the first protrusion includes a first portion 321, and a second portion 322 and a third portion 323 placed on two sides of the first portion 321, respectively.

Here, the elastic force of the elastic body (e.g., a first sub elastic body) connected to the first portion 321 is greater than the elastic force of the elastic body (e.g., a second sub elastic body) connected to the second portion 322 and the elastic force of the elastic body (e.g., a third sub elastic body) connected to the third portion 323.

Similarly, the second protrusion is divided into a plurality of portions 1321, 1322, and 1323.

For example, the second protrusion includes a fourth portion 1321, and a fifth portion 1322 and a sixth portion 1323 placed on two sides of the fourth portion 1321, respectively. Here, the elastic force of the elastic body (e.g., a fourth sub elastic body) connected to the fourth portion 1321 is greater than the elastic force of the elastic body (e.g., a fifth sub elastic body) connected to the fifth portion 1322 and the elastic force of the elastic body (e.g., a sixth sub elastic body) connected to the sixth portion 1323.

When the expander 300 is viewed on the basis of the first direction X, the first portion 321 and the fourth portion 1321 are placed at the furthest position. For example, a distance between the first portion 321 and the fourth portion 1321 is greater than a distance between the second portion 322 and the fifth portion 1322 and/or a distance between the third portion 323 and the sixth portion 1323.

In this way, by increasing the elastic force of the first portion 321 and the fourth portion 1321 which are farthest from each other when viewed on the basis of the first direction X, the force of pulling the dicing tape 24 in the first direction X may be increased.

Referring to FIG. 16, a third protrusion 360 is placed inside the third groove 380 to abut against the first protrusion 320. Further, a fourth protrusion 1360 is placed inside the fourth groove 1380 to abut against the second protrusion 1320.

As described above, when the expander 300 is viewed on the basis of the first direction X, the third protrusion 360 and the fourth protrusion 1360 are placed at the furthest position. In this way, by additionally installing the third protrusion 360 and the fourth protrusion 1360 in the farthest region when viewed on the basis of the first direction X, the force of pulling the dicing tape 24 in the first direction X may be increased.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor manufacturing equipment comprising:
a first clamp fixing a dicing tape, on which a plurality of divided dies are disposed, and configured to ascend and descend; and
a first expander adjacent to the first clamp and including a body, a first protrusion connected to the body, and a second protrusion connected to the body and spaced apart from the first protrusion,
wherein, when no pressure is exerted on the first protrusion and the second protrusion, the first protrusion and the second protrusion protrude from the body, and
wherein, when a pressure is exerted on the first protrusion and the second protrusion, the first protrusion and the second protrusion descend into the body depending on a magnitude of the pressure exerted on the first protrusion and the second protrusion.

2. The semiconductor manufacturing equipment of claim 1,
wherein, as the first clamp descends from a standby position, the dicing tape exerts pressure on the first protrusion and the second protrusion, and the dicing tape, the first protrusion and the second protrusion descend together.

3. The semiconductor manufacturing equipment of claim 2,
wherein, when the first clamp is positioned at a first height, the dicing tape is brought into contact with the first protrusion and the second protrusion,
wherein, as the first clamp descends below the first height, the dicing tape lowers the first protrusion and the second protrusion, and
wherein, when the first clamp descends to a second height, the dicing tape is brought into contact with upper surfaces of the first protrusion, the second protrusion and the body.

4. The semiconductor manufacturing equipment of claim 1,
wherein each of the plurality of divided dies has a first length in a first direction and a second length in a second direction crossing the first direction, and the first length is shorter than the second length.

5. The semiconductor manufacturing equipment of claim 4,
wherein the first protrusion and the second protrusion are spaced apart from each other in the first direction.

6. The semiconductor manufacturing equipment of claim 4,
wherein the body has an annular shape, and
wherein the first protrusion and the second protrusion are disposed at symmetrical positions in the first direction on a basis of a center of the annular shape.

7. The semiconductor manufacturing equipment of claim 6,
wherein each of the first protrusion and the second protrusion has an arc shape.

8. The semiconductor manufacturing equipment of claim 6,
wherein the first expander further includes:
a first groove and a second groove spaced apart from each other inside the body;
a first elastic body disposed inside the first groove; and
a second elastic body disposed inside the second groove,
wherein the first protrusion is connected to the first elastic body and is configured to move along inner walls of the first groove, and
wherein the second protrusion is connected to the second elastic body and is configured to move along inner walls of the second groove.

9. The semiconductor manufacturing equipment of claim 6,
wherein the first protrusion includes a first portion, a second portion, and a third portion, wherein the second portion and the third portion are disposed on both sides of the first portion, respectively, and
wherein an elastic force of a first elastic body connected to the first portion is greater than an elastic force of a second elastic body connected to the second portion and an elastic force of a third elastic body connected to the third portion.

10. The semiconductor manufacturing equipment of claim 1, further comprising:
a die ejector disposed below the dicing tape, and configured to push up and select a die that is to be picked up, among the plurality of divided dies.

11. The semiconductor manufacturing equipment of claim 1, comprising:
a first stage and a second stage,
wherein the first clamp and the first expander are disposed on the first stage,
wherein the second stage includes a second clamp and a second expander, wherein the second clamp is configured to ascend and descend, wherein the second expander is disposed inside the second clamp and has a flat upper surface, and
wherein the first stage or the second stage is selectively used depending on shapes of the plurality of divided dies.

12. An expander comprising:
an annular-shaped body;
a first groove and a second groove spaced apart from each other inside the annular-shaped body:
a first elastic body disposed inside the first groove;
a second elastic body disposed inside the second groove;
a first protrusion, which is connected to the first elastic body, standing by at a first position that is protruding from the annular-shaped body, wherein the first protrusion is configured to enter the first groove when a force is applied to the first protrusion by a dicing tape, and is configured to move to a second position; and
a second protrusion, which is connected to the second elastic body, standing by at a third position that is protruding from the annular-shaped body, wherein the second protrusion is configured to enter the second groove when a force is applied to the second protrusion by the dicing tape, and is configured to move to a fourth position.

13. The expander of claim 12,
wherein a plurality of divided dies are attached to the dicing tape,
wherein each of the plurality of divided dies has a first length in a first direction, and a second length in a second direction crossing the first direction, wherein the first length is shorter than the second length, and
wherein the first groove and the second groove are spaced apart from each other in the first direction.

14. The expander of claim 13,
wherein the first protrusion and the second protrusion are placed at symmetrical positions in the first direction on a basis of a center of the annular-shaped body.

15. The expander of claim 14,
wherein each of the first protrusion and the second protrusion has an arc shape.

16. The expander of claim 12,
wherein the first protrusion includes a first portion, a second portion, and a third portion, wherein the second portion and the third portion are disposed on both sides of the first portion, respectively,
wherein the second protrusion includes a fourth portion, a fifth portion, and a sixth portion, wherein the fifth portion and the sixth portion are disposed on both sides of the fourth portion, respectively,
wherein the first elastic body includes a first sub elastic body, a second sub elastic body, and a third sub elastic body, wherein the second elastic body includes a fourth sub elastic body, a fifth sub elastic body, and a sixth sub elastic body,
wherein an elastic force of the first sub elastic body connected to the first portion is greater than an elastic force of the second sub elastic body connected to the second portion and an elastic force of the third sub elastic body connected to the third portion, and
wherein an elastic force of the fourth sub elastic body connected to the fourth portion is greater than an elastic force of the fifth sub elastic body connected to the fifth portion and an elastic force of the sixth sub elastic body connected to the sixth portion.

17. A semiconductor manufacturing equipment comprising:
a first clamp fixing a dicing tape, on which a plurality of divided dies are disposed, and is configured to ascend and descend;
a die ejector disposed below the dicing tape, and configured to select a die that is to be picked up, among the plurality of divided dies; and
a first expander disposed between the first clamp and the die ejector and configured to expand the dicing tape as the first clamp descends,
wherein the first expander includes:
an annular-shaped body;
a first groove and a second groove which are disposed inside the annular-shaped body and disposed symmetrically with each other on a basis of a center of the annular-shaped body;
a first elastic body disposed inside the first groove;
a second elastic body disposed inside the second groove;
a first protrusion, which is connected to the first elastic body, standing by at a first position that is protruding from the annular-shaped body, wherein the first protrusion is configured to move to a second position along the first groove when a force is applied to the first protrusion by the dicing tape; and
a second protrusion, which is connected to the second elastic body, standing by at a third position that is protruding from the annular-shaped body, wherein the second protrusion is configured to move to a fourth position along the second groove when a force is applied to the second protrusion by the dicing tape.

18. The semiconductor manufacturing equipment of claim 17,
wherein each of the plurality of divided dies has a first length in a first direction, and a second length in a second direction crossing the first direction, and the first length is shorter than the second length.

19. The semiconductor manufacturing equipment of claim 18,
wherein the first groove and the second groove are spaced apart from each other in the first direction.

20. The semiconductor manufacturing equipment of claim 17, comprising:
a first stage and a second stage,
wherein the first clamp and the first expander are disposed on the first stage,
wherein the second stage includes a second clamp and a second expander, wherein the second clamp is configured to ascend and descend, wherein the second expander is disposed inside the second clamp and has a flat upper surface, and
wherein the first stage or the second stage is selectively used depending on shapes of the plurality of divided dies.
